(19) United States
(12) Patent Application Publication
(10) Pub. No.: US 2022/0299567 A1
(43) Pub. Date: Sep. 22, 2022

(54) METHOD AND DEVICE FOR TESTING INTEGRATED CIRCUIT

(71) Applicant: CHANGXIN MEMORY TECHNOLOGIES, INC., Hefei City (CN)

(72) Inventor: Zhi Qu, Hefei (CN)

(21) Appl. No.: 17/487,678

(22) Filed: Sep. 28, 2021

Related U.S. Application Data
(63) Continuation of application No. PCT/CN2021/105734, filed on Jul. 12, 2021.

(30) Foreign Application Priority Data
Mar. 17, 2021 (CN) 202110286510.X

(51) Int. Cl. G01R 31/319; G01R 31/3185

(52) U.S. Cl. CPC G01R 31/31905; G01R 31/3191; G01R 31/318508; G01R 31/318572

(57) ABSTRACT

Embodiments of the disclosure provide a method and device for testing an integrated circuit (IC). Calibration parameters of test boards are determined respectively by acquiring identification information of the test boards, and then each of to-be-tested devices in each of the test boards is tested respectively based on the calibration parameters of the test boards. According to the embodiments of the disclosure, the calibration parameters of the test boards are determined respectively according to the identification information corresponding to the test boards, therefore when different types of test boards are adopted by a test machine, each type of test boards may acquire the accurate calibration parameter, so that the accuracy of a test result is ensured, the mixed test of multiple types of test boards is implemented, furthermore, the test efficiency is improved and the test cost is reduced.

### CROSS-REFERENCE TO RELATED APPLICATIONS

This is a continuation application of International Patent Application No. PCT/CN2021/105734, filed on Jul. 12, 2021, which claims priority to Chinese Patent Application No. 202110286510.X, filed on Mar. 17, 2021 and entitled “METHOD AND DEVICE FOR TESTING INTEGRATED CIRCUIT”. The entire contents of International Patent Application No. PCT/CN2021/105734 and Chinese Patent Application No. 202110286510.X are incorporated herein by reference in their entireties.

### BACKGROUND

In the technical field of integrated circuits (ICs), in order to enable components such as a chip and the like to achieve an expected application effect, testing of the chip becomes an essential link in production and usage of the chip.

At present, when the chip is tested, a batch of chips are usually plugged into multiple test boards, and then the chips plugged into the test boards are respectively turned on in sequence to be tested. Before testing, a test machine needs to determine a signal compensation data based on any one of the test boards, and calibrate each of the test boards according to the signal compensation data, thereby ensuring the accuracy of a test result.

However, with the increase of chip production capacity and by consideration of the test cost, the test machine may simultaneously adopt different types of test boards. Because different types of test boards have different calibration parameters, the accuracy of the test result is inevitably affected when each of the test boards is still calibrated by using the signal compensation data determined based on any one of the test boards.

### SUMMARY

Embodiments of the disclosure relate to the technical field of integrated circuits (ICs), and in particular relates to a method and device for testing an IC.

According to a first aspect, the disclosure provides a method for testing an IC. The method is executed by a test machine, and includes the following operations.

Identification information of test boards on the test machine is acquired, the test machine is provided with multiple partitions, each of which is provided with multiple slots, the test boards are plugged into different slots and each has multiple to-be-tested devices plugged therein.

Calibration parameters of the test boards are determined according to the identification information of the test boards, here different types of test boards have different calibration parameters.

Each of the to-be-tested devices in each of the test boards is tested based on the calibration parameters of the test boards.

According to a second aspect, the disclosure provides an apparatus for testing an IC, including at least one processor and a memory.

The memory is configured to store instructions executable by the at least one processor.

The at least one processor is configured to: acquire identification information of test boards on a test machine provided with multiple partitions, each of which provided with multiple slots, the test boards plugged into different slots and each having multiple to-be-tested devices plugged therein; determine, according to the identification information of the test boards, calibration parameters of the test boards, wherein different types of test boards have different calibration parameters; and test each of the to-be-tested devices in each of the test boards based on the calibration parameters of the test boards.

According to a third aspect, the disclosure provides a non-transitory computer-readable storage medium having stored therein computer executable instructions that, when executed by a processor, causes the following operations.

Identification information of test boards on a test machine is acquired, the test machine is provided with multiple partitions, each of which is provided with multiple slots, the test boards are plugged into different slots and each has multiple to-be-tested devices plugged therein.

Calibration parameters of the test boards are determined according to the identification information of the test boards, here different types of test boards have different calibration parameters.

Each of the to-be-tested devices in each of the test boards is tested based on the calibration parameters of the test boards.

### BRIEF DESCRIPTION OF THE DRAWINGS

In order to describe the technical solutions of the embodiments of the disclosure or the related art more clearly, the accompanying drawings required for describing the embodiments of the disclosure or the related art are briefly introduced as follows. Apparently, the accompanying drawings in the following descriptions show only some embodiments of the disclosure, and those of ordinary skill in the art may still derive other drawings from the accompanying drawings without paying any creative efforts.

FIG. 1 is a schematic structural diagram of a test board provided by an embodiment of the disclosure.

FIG. 2 is a first schematic flowchart of a method for testing an IC provided by an embodiment of the disclosure.

FIG. 3 is a second schematic flowchart of a method for testing an IC provided by an embodiment of the disclosure.

FIG. 4 is a schematic diagram of a program module of an apparatus for testing an IC provided by an embodiment of the disclosure.

FIG. 5 is a schematic diagram of a hardware structure of an electronic device provided by an embodiment of the disclosure.

### DETAILED DESCRIPTION

In order to make the objects, technical solutions and advantages of the embodiments of the disclosure clearer, the technical solutions of the embodiments of the disclosure will be clearly and completely described below with reference to the accompanying drawings of the embodiments of the disclosure. It is apparent that the described embodiments are part of the embodiments of the disclosure, rather than all of the embodiments. All other embodiments obtained by those of ordinary skill in the art without paying any creative efforts based on the embodiments of the disclosure fall within the scope of protection of the disclosure. In addition, while the disclosure herein is introduced in terms of one or more exemplary examples, it should be understood that various aspects of the disclosure may also constitute a complete embodiment alone.

It should be noted that brief descriptions of terms in the disclosure are only intended to easily understand the embodiments described below and are not intended to limit the embodiments of the disclosure. These terms should be understood according to their ordinary and usual meaning, unless stated otherwise.

In addition, the terms “include” and “have”, as well as any variations thereof, are intended to cover but not exclusively include items, e.g., a product or device including a series of components is not limited to those components listed clearly, but may include other components not listed clearly or inherent to such product or device.

In the technical field of ICs, in order to enable a chip to achieve an expected application effect, an aging test of the chip is widely applied to a reliability test of an IC. After a test board is plugged into a test machine, a signal may be led to pins of a tested chip through a test channel circuit integrated in the test board. Therefore, the reliability of the tested chip is evaluated.

In a practicable implementation of the disclosure, the adopted test machine is provided with multiple partitions, each of which is provided with multiple slots, the test boards are plugged into different slots and each has multiple to-be-tested devices plugged therein.

In an embodiment, the to-be-tested device may be a semiconductor device such as a chip, etc.

Exemplarily, the test machine is provided with 2 test chambers. Each of the test chambers is provided with 2 partitions. Each of the partitions is provided with 12 slots. A test board may be plugged into each of the slots correspondingly.

In some embodiments, each of the test boards includes a line concentration board integrated with test-related peripheral circuits. The line concentration board may be plugged into a line concentration board plugging area of the test board. The line concentration board plugging area is provided with one or more line concentration board sockets, that is, one or more line concentration boards may be plugged into the line concentration board plugging area. Each of the test boards further includes a chip plugging area. The chip plugging area is provided with multiple chip sockets for plugging multiple to-be-tested chips.

The test-related peripheral circuits matched with the to-be-tested chips plugged into the chip plugging area are integrated into the line concentration board plugged into the line concentration board plugging area, and the number of the line concentration boards plugged into the line concentration board plugging area is consistent with the number of types of the to-be-tested chips plugged into the chip plugging area.

In order to better understand the disclosure, please refer to FIG. 1, FIG. 1 is a schematic structural diagram of a test board provided by an embodiment of the disclosure.

In some embodiments, a chip plugging area 10 of a test board 100 is provided with multiple chip sockets 12 connected in parallel with one another, where multiple to-be-tested chips may be plugged. A line concentration board plugging area 20 of the test board 100 is provided with a line concentration board socket 22 where a line concentration board S matched with the to-be-tested chip is plugged.

In a practical application process, there are various types of the tested chips, and the packaging types and the arrangement of pins of the tested chips are also different, so that different types of test boards need to be used for different types of tested chips.

In the related art, before an aging test, a test machine needs to determine a signal compensation data based on any one of the test boards, and calibrate each of the test boards according to the signal compensation data, thereby ensuring the accuracy of a test result. However, because different types of test boards have different calibration parameters, the accuracy of the test result is inevitably affected when each type of test boards is still calibrated by using the signal compensation data determined based on any one of the test boards.

In order to solve the above-mentioned technical problem, the embodiment of the disclosure provides a method for testing an IC. In the method, the calibration parameters of the test boards are determined respectively according to the identification information corresponding to the test boards, therefore when different types of test boards are adopted by the test machine, each type of test boards may acquire the accurate calibration parameter, so that the accuracy of a test result is ensured, the mixed test of multiple types of test boards is implemented, furthermore, the test efficiency is improved and the test cost is reduced. Specific implementations thereof are described in detail by the following embodiments.

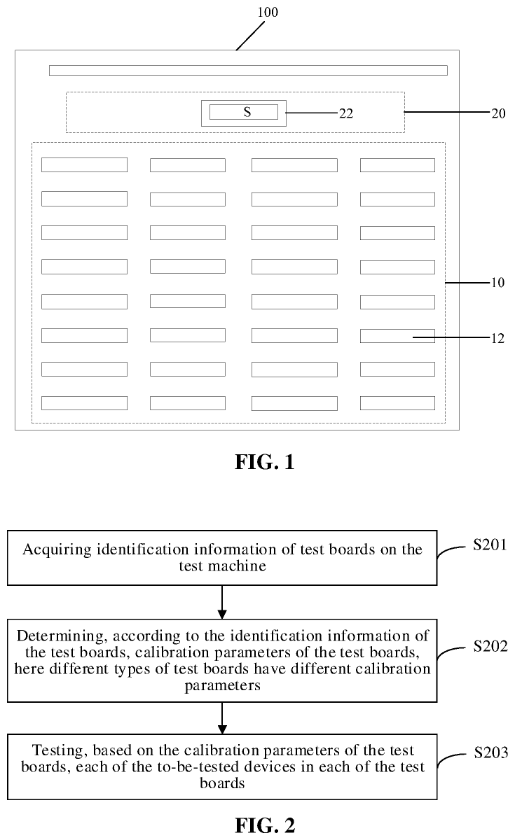

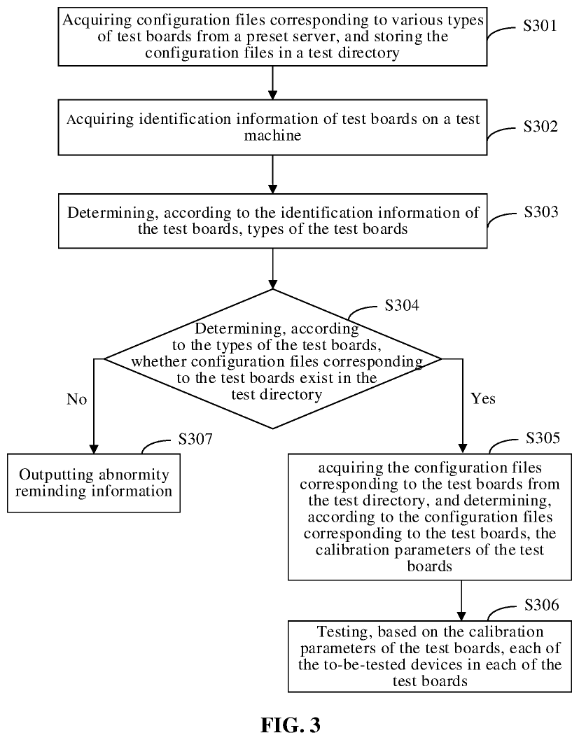

Referring to FIG. 2, FIG. 2 is a first schematic flowchart of a method for testing an IC provided by an embodiment of the disclosure. In a practicable implementation, the method for testing an IC includes the following operations.

In operation S201, identification information of test boards on the test machine is acquired.

Multiple to-be-tested devices are plugged into each of the test boards.

It should be understood that each of the test boards will have unique identification information during production, such as unique ID information, etc. The identification information may be configured to distinguish information such as the types or test parameters of the test boards, etc.

According to the embodiment of the disclosure, before testing, the test machine may acquire the identification information of the test boards on the test machine through a scanning device or a sensor. Or, a tester may manually input the identification information of the test boards into the test machine.

In operation S202, calibration parameters of the test boards are determined according to the identification information of the test boards, here different types of test boards have different calibration parameters.

In some embodiments, after the identification information of the test boards is acquired by the test machine, types of the test boards may be determined according to the identification information of the test boards, and the calibration parameters of the test boards may be determined according to pre-determined correspondences between the types and the calibration parameters of the test boards.

In order to better understand the disclosure, it is assumed that there are three types of test boards, i.e., types A, B and C. The calibration parameters of the three types are calibration parameter a, calibration parameter b and calibration parameter c respectively. Meanwhile, it is assumed that the test machine is provided with 5 test boards.

after the test machine acquires the identification information of the test boards on the test machine, in response to determining the types of the test boards to be type A, type A, type B, type B and type C respectively according to the identification information of the test boards, the calibration parameters of the test boards on the test machine may be determined to be the calibration parameter a, the calibration parameter a, the calibration parameter b, the calibration parameter b and the calibration parameter c respectively.

In operation S203, each of the to-be-tested devices in each of the test boards is tested based on the calibration parameters of the test boards.

In the embodiment of the disclosure, after the calibration parameters of the test boards are determined, each of the to-be-tested devices in each of the test boards may be tested.

In an embodiment, the to-be-tested device may be a semiconductor device such as a chip, etc. That is, the method for testing an IC provided by the embodiment of the disclosure may be applied to the aging test of the chip.

In the embodiment of the disclosure, when different types of test boards are adopted by the test machine, calibration parameters of test boards are determined respectively by acquiring identification information of the test boards, so that each type of test boards may acquire the accurate calibration parameter, and then each of to-be-tested devices in each of the test boards is tested respectively based on the calibration parameters of the test boards, therefore the accuracy of a test result is ensured, the mixed test of multiple types of test boards is implemented, furthermore, the test efficiency is improved and the test cost is reduced.

Based on the contents described in the above-mentioned embodiment, please refer to FIG. 3, FIG. 3 is a second schematic flowchart of a method for testing an IC provided by an embodiment of the disclosure, in a practicable implementation, the method for testing an IC includes the following operations.

In operation S301, configuration files corresponding to various types of test boards are acquired from a preset server, and the configuration files are stored in a test directory.

In the embodiment of the disclosure, the configuration files corresponding to various types of test boards may be pre-stored in the server.

In an embodiment, the configuration files may be TPD files. As for a UTD_TpdDataSettings.txt Format file in the test machine, the file includes the following information.

FILE_1 TPD_xxx_4D0A_revx.txt

FILE_2 TPD_xxx_4D1A_revx.txt

. . .

FILE_23 TPD_xxx_4D0A_revx.txt

FILE_24 TPD_xxx_4D1A_revx.txt

Each of the test boards corresponds to a configuration file information, for example, the configuration file corresponding to the first test board is FILE_1, the configuration file corresponding to the second test board is FILE_2 . . . , the configuration file corresponding to the 23rd test board is FILE_23, and the configuration file corresponding to the 24th test board is FILE_24.

4D0A and 4D1A are the identification information of the test boards. Exemplarily, 4D0A may means that a to-be-tested device type is DDR4, a product type is DDR, the number of packaging solder balls is 78, and a Printed Circuit Board (PCB) manufacturer is ADV.

In operation S302, identification information of test boards on a test machine is acquired.

In operation S303, types of the test boards are determined according to the identification information of the test boards.

In an embodiment, the identification information may include at least one of a to-be-tested device type, a product type, packaging information or manufacturer information of the test board.

The to-be-tested device type may be configured to represent the specific type of the to-be-tested device, such as DDR4, LPDDR4, etc. The product type may be configured to represent the product type of the to-be-tested device, such as DDR, LPDDR, etc. The packaging information may be configured to represent packaging information of a solder ball array of the to-be-tested device.

Exemplarily, please refer to Table 1, Table 1 is a schematic composition information table of the above-mentioned identification information.

TABLE 1
Schematic Composition Information Table of
Identification Information of Test Boards

| Bit | 1 | 2 | 3 | 4 |
|---|---|---|---|---|
| Meaning | To-be- | Product | Packaging | Manufacturer |
| | tested | type | information | information |
| | device type | | | |
| Example | 4: | D: | 0: 78Ball | A: ADV |
| | DDR4 | DDR4 | | PCB(JPN) + |
| | | | | socket(Okins) |
| | | | | 352DUT |
| | A: | 1: | 1: 96Ball | B: ADV |
| | LPDDR4 | LPDDR | | PCB(CHN) + |
| | | | | socket(Okins) |
| | | | | 352DUT |
| | | | 2: 200Ball | C: ADV |
| | | | | PCB(CHH) + |
| | | | | socket(Hicon) |
| | | | | w/fuse 352DUT |

According to the table, it is known that 4D0A contains information of DDR4+DDR+78Ball+JPN which may be configured to represent that the to-be-tested device type corresponding to the test board is DDR4, the product type is DDR, the number of packaging solder balls is 78, and the PCB manufacturer is JPN; and 4D1A contains information of DDR4+DDR+96Ball+JPN which may be configured to represent that the to-be-tested device type corresponding to the test board is DDR4, the product type is DDR, the number of packaging solder balls is 96, and the PCB manufacturer is JPN.

In operation S304, whether configuration files corresponding to the test boards exist in the test directory is determined according to the types of the test boards. When the configuration files corresponding to the test boards exist in the test directory, operations S305 and S306 are continued to be executed; otherwise, operation S307 is executed.

In operation S305, the configuration files corresponding to the test boards are acquired from the test directory, and the calibration parameters of the test boards are determined according to the configuration files corresponding to the test boards.

For example, it is assumed that the test machine is provided with 6 test boards of two types, the configuration files corresponding to the 6 test boards are as follows.

FILE_1 TPD_T114624_A12A_200B_rev01.txt

FILE_2 TPD_T114624_A12A_200B_rev01.txt

FILE_3 TPD_T114624_A12A_200B_rev01.txt

FILE_4 TPD_T114624_A12B_200B_rev01.txt

FILE_5 TPD_T114624_A12B_200B_rev01.txt

FILE_6 TPD_T114624_A12B_200B_rev01.txt

The calibration parameter of each of the test boards is determined as follows.

TpdData_01_0001t.cal

TpdData_02_0001t.cal

TpdData_03_0001t.cal

TpdData_04_0002t.cal

TpdData_05_0002t.cal

TpdData_06_0002t.cal

In some embodiments, historical configuration files stored in the test directory are deleted before the configuration files corresponding to the test boards are acquired from the test directory, and the situation where the calibration parameter is not matched with the type of the test board due to position change of the test board before testing is prevented.

In operation S306, each of the to-be-tested devices in each of the test boards is tested based on the calibration parameters of the test boards.

In operation S307, abnormity reminding information is output.

The abnormity reminding information is configured to remind a tester to acquire the configuration files corresponding to the test boards from the preset server, and store the configuration files in the test directory.

In some embodiments, after the tester acquires the configuration files corresponding to the test boards from the server again and stores the configuration files in the test directory, operations S305 and S306 may be continued to be executed.

According to the method for testing an IC provided by the embodiments of the disclosure, types of the test boards may be determined by acquiring the identification information of the test boards, and then the configuration files corresponding to the test boards may be acquired according to the types of the test boards, so that the calibration parameters corresponding to the test boards may be determined. Therefore, when different types of test boards are adopted by the test machine, each type of test boards may acquire the accurate calibration parameter, so that the accuracy of a test result is ensured, the mixed test of multiple types of test boards is implemented, furthermore, the test efficiency is improved and the test cost is reduced.

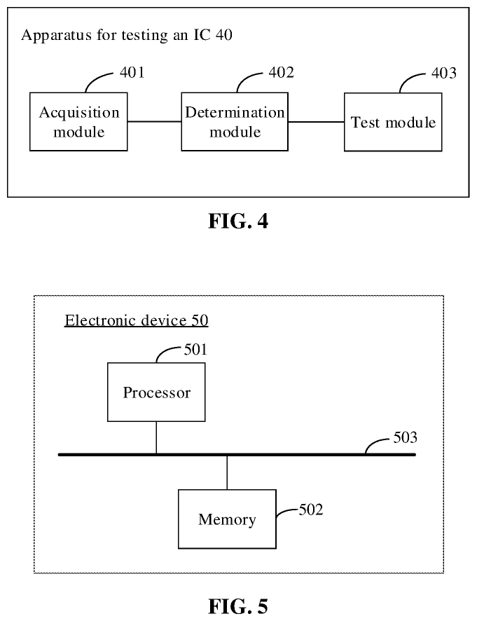

Based on the contents described in the above-mentioned embodiments, the embodiments of the disclosure further provide an apparatus for testing an IC applied to a test machine. Please Refer to FIG. 4, FIG. 4 is a schematic diagram of a program module of an apparatus for testing an IC provided by an embodiment of the disclosure, the apparatus for testing an IC 40 includes an acquisition module 401, a determination module 402, and a test module 403.

The acquisition module 401 is configured to acquire identification information of test boards on a test machine.

Multiple to-be-tested devices are plugged into each of the test boards.

The determination module 402 is configured to determine, according to the identification information of the test boards, calibration parameters of the test boards, here different types of test boards have different calibration parameters.

The test module 403 is configured to test, based on the calibration parameters of the test boards, each of the to-be-tested devices in each of the test boards.

It should be understood that the term “module” used in the disclosure may refer to any known or future developed hardware, software, firmware, artificial intelligence (AI), fuzzy logic, or combination of hardware and/or software codes capable of performing functions associated with the element.

According to the apparatus 40 for testing an IC provided by the embodiment of the disclosure, when different types of test boards are adopted by the test machine, calibration parameters of test boards are determined respectively by acquiring identification information of the test boards, so that each type of test boards may acquire the accurate calibration parameter, and then each of to-be-tested devices in each of the test boards is tested respectively based on the calibration parameters of the test boards, therefore the accuracy of a test result is ensured, the mixed test of multiple types of test boards is implemented, furthermore, the test efficiency is improved and the test cost is reduced.

In a practicable implementation, the determination module 402 is further configured to execute the following operations.

Types of the test boards are determined according to the identification information of the test boards. The calibration parameters of the test boards are determined according to the types of the test boards.

In a practicable implementation, the acquisition module 401 is further configured to execute the following operations.

Configuration files corresponding to various types of test boards are acquired from a preset server, and the configuration files are stored in a test directory.

In a practicable implementation, the determination module 402 is further configured to execute the following operations.

Whether configuration files corresponding to the test boards exist in the test directory is determined according to the types of the test boards. The configuration files corresponding to the test boards are acquired from the test directory, when the configuration files corresponding to the test boards exist in the test directory. The calibration parameters of the test boards are determined according to the configuration files corresponding to the test boards.

In a practicable implementation, the apparatus further includes a reminding module configured to execute the following operations.

Abnormity reminding information is output when a configuration file corresponding to at least one of the test boards does not exist in the test directory, the abnormity reminding information is configured to remind a tester to acquire the configuration files corresponding to the test boards from the preset server, and store the configuration files in the test directory.

In a practicable implementation, the determination module 402 is further configured to execute the following operations.

Historical configuration files stored in the test directory are deleted before testing.

In a practicable implementation, the implemented identification information includes at least one of a to-be-tested device type, a product type, packaging information or manufacturer information of the test board.

It should be noted that specific contents executed by the acquisition module 401, the determination module 402 and the test module 403 in the above-mentioned embodiment may refer to related contents described with respect to the embodiments shown in FIG. 2 and FIG. 3 and will not be elaborated here.

According to the apparatus for testing an IC provided by the embodiment of the disclosure, types of test boards may be determined by acquiring identification information of the test boards, and then configuration files corresponding to the test boards may be acquired according to the types of the test boards, so that calibration parameters corresponding to the test boards may be determined, therefore when different types of test boards are adopted by the test machine, each type of test boards may acquire the accurate calibration parameter, so that the accuracy of a test result is ensured, the mixed test of multiple types of test boards is implemented, furthermore, the test efficiency is improved and the test cost is reduced.

Furthermore, based on the contents described in the above-mentioned embodiments, the embodiments of the disclosure further provide an electronic device. The electronic device may be the test machine or part of the test machine and includes at least one processor and a memory. The memory stores computer executable instructions. The at least one processor executes the computer executable instructions stored in the memory, to implement operations of the method for testing an IC as described in the above-mentioned embodiments, which are not elaborated here.

In order to better understand the disclosure, please refer to FIG. 5, FIG. 5 is a schematic diagram of a hardware structure of an electronic device provided by an embodiment of the disclosure.

As shown in FIG. 5, the electronic device 50 of the embodiment includes a processor 501 and a memory 502.

The memory 502 is configured to store computer executable instructions.

The processor 501 is configured to execute the computer executable instructions stored in the memory to implement operations of the method for testing an IC as described in the above-mentioned embodiments, and specific implementation thereof may refer to associated descriptions of the above-mentioned method embodiments.

In an embodiment, the memory 502 may be an independent memory or integrated with the processor 501.

When the memory 502 is disposed independently, the device further includes a bus 503 configured to connect the memory 502 and the processor 501.

Furthermore, based on the contents described in the above-mentioned embodiments, the embodiments of the disclosure further provide a computer-readable storage medium having stored therein computer executable instructions, and the computer executable instructions implement operations of the method for testing an IC as described in the above-mentioned embodiments, when being executed by a processor.

Furthermore, based on the contents described in the above-mentioned embodiments, the embodiments of the disclosure further provide a computer program product including a computer program, here the computer program implements operations of the method for testing an IC as described in the above-mentioned embodiments, when being executed by a processor.

In several embodiments provided by the disclosure, it should be understood that the disclosed device and method may be implemented in other manners. For example, the above-mentioned device embodiment is merely illustrative, e.g., the division of the modules is only a logical function division, and in practice, there may be additional divisions, e.g., multiple modules may be combined or integrated into another system, or some features may be omitted or may not be executed. Furthermore, coupling or direct coupling or communication connection between shown or discussed components may be indirect coupling or communication connection through some interfaces, apparatus or modules, and may be in electric, mechanical or another form.

The modules described as separate components may be or may not be physically separated. The components shown as modules may be or may not be physical units, i.e., may be located in one place, or may be distributed over multiple network units. All or part of the modules may be selected according to actual needs to achieve the purpose of the solutions of the embodiments.

In addition, each of the functional modules in each of the embodiments of the disclosure may be integrated in a processing unit, or each of the modules may exist independently and physically, or two or more modules may be integrated in one unit. The unit formed by the modules may be implemented in the form of hardware, or may be implemented in the form of a hardware and a software functional unit.

The above integrated modules implemented in the form of software functional modules, may be stored in a computer-readable storage medium. The software functional modules are stored in the storage medium and include several instructions for enabling a computer device (which may be a personal computer, a server, a network device, or the like) or a processor to execute part of operations of the method according to each of the embodiments of the disclosure.

It should be understood that the processor may be a Central Processing Unit (CPU), or may be another general-purpose processor, a Digital Signal Processor (DSP), an Application Specific Integrated Circuit (ASIC), or the like. The general-purpose processor may be a microprocessor, or the processor may be any conventional processor and the like. The operations of the method disclosed by the disclosure may be implemented directly as being executed and completed by a hardware processor or by the combination of hardware and software modules in the processor.

The memory may include a high-speed Random Access Memory (RAM) memory, or may include a Non-Volatile Memory (NVM), such as at least one disk storage, or may be a U-disk, a removable hard disk, a Read-Only Memory (ROM), a magnetic disk or an optical disk, or the like.

The bus may be an Industry Standard Architecture (ISA) bus, a Peripheral Component Interconnection (PCI) bus, or an Extended Industry Standard Architecture (EISA) bus, or the like. The bus may be divided into an address bus, a data bus, a control bus, etc. For ease of representation, the bus in the accompanying drawings of the disclosure is not limited to only one bus or one type of bus.

The above-mentioned storage medium may be implemented by any type of volatile or non-volatile memory device, or a combination thereof, such as a Static Random Access Memory (SRAM), an Electrically Erasable Programmable Read-Only Memory (EEPROM), an Erasable Programmable Read-Only Memory (EPROM), a Programmable Read-Only Memory (PROM), a ROM, a magnetic memory, a flash memory, a magnetic disk or an optical disk. The storage medium may be any available medium that may be accessed by a general-purpose or special-purpose computer.

An exemplary storage medium is coupled to the processor to enable the processor to read information from the storage medium, and write information to the storage medium. Of course, the storage medium may also be a component of the processor. The processor and the storage medium may be located in ASICs. Of course, the processor and the storage medium may be located in an electronic device or a master device as discrete components.

Those of ordinary skill in the art may understand that all or part of operations of the above-mentioned method embodiments may be accomplished with hardware associated with program instructions. The program may be stored in a computer-readable storage medium. When the program is executed, the operations of the above-mentioned method embodiments are executed. The storage medium includes various mediums capable of storing program codes, such as an ROM, an RAM, a magnetic disk or an optical disk, etc.

Finally, it should be noted that the foregoing embodiments are merely intended to describe the technical solutions of the disclosure, but are not intended to limit the disclosure. Although the disclosure is described in detail with reference to the foregoing embodiments, those ordinary skill in the art should understand that they may still make modifications to the technical solutions described in the foregoing embodiments or make equivalent replacements to all or part of technical features thereof, without making the essences of corresponding technical solutions departing from the scopes of the technical solutions of the embodiments of the disclosure.

1. A method for testing an integrated circuit (IC), executed by a test machine, comprising:
acquiring identification information of test boards on the test machine provided with a plurality of partitions, each of which provided with a plurality of slots, the test boards plugged into different slots and each having a plurality of to-be-tested devices plugged therein;
determining, according to the identification information of the test boards, calibration parameters of the test boards, wherein different types of test boards have different calibration parameters; and
testing, based on the calibration parameters of the test boards, each of the to-be-tested devices in each of the test boards.

2. The method of claim 1, wherein determining, according to the identification information of the test boards, calibration parameters of the test boards comprises:
determining, according to the identification information of the test boards, types of the test boards; and
determining, according to the types of the test boards, the calibration parameters of the test boards.

3. The method of claim 2, further comprising before acquiring the identification information of the test boards:
acquiring configuration files corresponding to various types of test boards from a preset server, and storing the configuration files in a test directory; and
determining, according to the types of the test boards, the calibration parameters of the test boards comprising:
determining, according to the types of the test boards, whether configuration files corresponding to the test boards exist in the test directory;
acquiring the configuration files corresponding to the test boards from the test directory, when the configuration files corresponding to the test boards exist in the test directory; and
determining, according to the configuration files corresponding to the test boards, the calibration parameters of the test boards.

4. The manufacturing method of claim 3, further comprising:
outputting abnormity reminding information configured to remind a tester to acquire the configuration files corresponding to the test boards from the preset server, when a configuration file corresponding to at least one of the test boards does not exist in the test directory, and storing the configuration files in the test directory.

5. The method of claim 3, further comprising before acquiring the configuration files corresponding to the test boards from the test directory:
deleting historical configuration files stored in the test directory.

6. The method of claim 1, wherein the identification information comprises at least one of a to-be-tested device type, a product type, packaging information or manufacturer information of the test board.

7. An apparatus for testing an integrated circuit (IC), comprising:
at least one processor; and
a memory configured to store instructions executable by the at least one processor;
wherein the at least one processor is configured to:
acquire identification information of test boards on a test machine provided with a plurality of partitions, each of which provided with a plurality of slots, the test boards plugged into different slots and each having a plurality of to-be-tested devices plugged therein;
determine, according to the identification information of the test boards, calibration parameters of the test boards, wherein different types of test boards have different calibration parameters; and
test each of the to-be-tested devices in each of the test boards based on the calibration parameters of the test boards.

8. The apparatus of claim 7, wherein the at least one processor is further configured to:
determine, according to the identification information of the test boards, types of the test boards; and
determine, according to the types of the test boards, the calibration parameters of the test boards.

9. The apparatus of claim 8, wherein the at least one processor is further configured to:
acquire configuration files corresponding to various types of test boards from a preset server, and store the configuration files in a test directory;
determine, according to the types of the test boards, whether configuration files corresponding to the test boards exist in the test directory;
acquire the configuration files corresponding to the test boards from the test directory, when the configuration files corresponding to the test boards exist in the test directory; and
determine, according to the configuration files corresponding to the test boards, the calibration parameters of the test boards.

10. The apparatus of claim 9, wherein the at least one processor is further configured to:
output abnormity reminding information configured to remind a tester to acquire the configuration files corresponding to the test boards from the preset server, when a configuration file corresponding to at least one of the test boards does not exist in the test directory, and store the configuration files in the test directory.

11. The apparatus of claim 9, wherein the at least one processor is further configured to:
delete historical configuration files stored in the test directory, before testing.

12. The apparatus of claim 7, wherein the identification information comprises at least one of a to-be-tested device type, a product type, packaging information or manufacturer information of the test board.

13. A non-transitory computer-readable storage medium having stored therein computer executable instructions that, when executed by a processor, causes operations of:
acquiring identification information of test boards on a test machine provided with a plurality of partitions, each of which provided with a plurality of slots, the test boards plugged into different slots and each having a plurality of to-be-tested devices plugged therein;
determining, according to the identification information of the test boards, calibration parameters of the test boards, wherein different types of test boards have different calibration parameters; and
testing, based on the calibration parameters of the test boards, each of the to-be-tested devices in each of the test boards.
